(19) United States
(12) Patent Application Publication
(10) Pub. No.: US 2003/0058148 A1
(43) Pub. Date: Mar. 27, 2003

(54) Multiple a-to-d converter scheme employing digital crossover filter

(76) Inventor: Timothy W. Sheen, Brighton, MA (US)

Correspondence Address: Legal Department, Teradyne, Inc., 321 Harrison Avenue, Boston, MA, 02118, US

(21) Appl. No.: 09/960,173

(22) Filed: Sep. 21, 2001

(51) Int. Cl. H03M 1/12

(52) U.S. Cl. 341/155

(57) ABSTRACT

A topology for converting analog signals to digital signals includes a plurality of analog-to-digital converters each having an analog input and a digital output. The analog inputs are coupled to one another, and the digital outputs are coupled to different inputs of a crossover filter. The crossover filter blends together the outputs of the converters to generate a single digital output, which has a uniform response, or a desired non-uniform response, and is substantially free of unwanted distortion.

### FIELD OF THE INVENTION

This invention relates generally to analog-to-digital converters, and, more particularly, to topologies employing multiple analog-to-digital converters for measuring test signals in automatic test equipment.

### BACKGROUND OF THE INVENTION

Analog and mixed signal testers routinely use analog-to-digital converters (ADCs) for measuring electronic signals. Converter topologies typically comprise a single ADC, which has adequate specifications for covering a wide range of expected input signals. Sometimes, however, a single converter cannot satisfy the full range of requirements and more than one converter is needed.

Prior multi-converter topologies have been used in which two or more converters are operated in parallel. According to one such technique, N substantially identical converters are operated in parallel at a sampling period of T seconds. Sample pulses to the converters are staggered, so that one converter is activated every T/N seconds. The outputs of the N converters are then interleaved to produce a single digital output that changes at N times the sample rate of the individual converters.

Although this technique increases timing resolution, it does not improve frequency response. If each converter has poor frequency response in a given range, the topology as a whole will also suffer from poor frequency response in that range.

According to another prior technique, different converters are optimized for measuring signals in different frequency bands. A user selects from among the converters, depending upon the expected frequency components of the input signal. The output of the selected converter is then used to supply the measurement result.

Although this topology can offer improved frequency response, it suffers from several drawbacks. In particular, the user must know the frequencies present in the input signal before the measurement is made. This can be problematic, because the very purpose of measuring the input signal may be to determine those components. To overcome this problem, the user may select different converters in turn and examine each resulting measurement. But then the user is left with different representations of the same input signal acquired at different instances of time. Parsing through these different representations to extract relevant test information can consume valuable test time. In addition, this technique is not amenable to examining the input signal as a whole. Instead of providing one digital representation of the analog input signal in its entirety, the topology provides multiple representations.

### SUMMARY OF THE INVENTION

With the foregoing background in mind, it is an object of the invention for a multi-converter topology to provide a single digital representation of an analog input signal.

It is another object of the invention to balance contributions from individual converters of a multi-converter topology to improve overall performance.

To achieve the foregoing object, as well as other objectives and advantages, a topology for converting analog signals to digital signals includes a plurality of analog-to-digital converters each having an analog input and a digital output. The analog inputs of the converters are coupled to one another, and the digital outputs are coupled to different inputs of a crossover filter. The crossover filter processes the outputs of the analog-to-digital converters to generate a single digital output that combines the outputs of the plurality of analog-to-digital converters.

### BRIEF DESCRIPTION OF THE DRAWINGS

Additional objects, advantages, and novel features of the invention will become apparent from a consideration of the ensuing description and drawings, in which

FIG. 1 is a simplified block diagram of a multi-converter topology according to the invention;

FIG. 2 is a simplified block diagram of a crossover filter used in the multi-converter topology of FIG. 1;

FIGS. 3A-3B are impulse responses of different digital filters shown to facilitate the description of the invention;

FIGS. 4A-4C are a block diagrams tracing the development of a simplified crossover filter having a uniform response;

FIG. 5 is a block diagram of an embodiment of a crossover filter having a non-uniform response; and

FIG. 6 is a block diagram of an alternative embodiment of the crossover filter for blending the outputs of greater than two ADCs.

### DETAILED DESCRIPTION OF THE PREFERRED EMBODIMENT

FIG. 1 shows an illustrative embodiment of a multi-converter topology according to the invention. An input signal “Analog In” is split into two circuit paths. The first path includes a first ADC 116, which preferably works well for converting low frequency input signals. The second path includes a second ADC 118, which preferably works well for converting high frequency input signals. The first and second ADCs 116 and 118 are preferably clocked simultaneously, to generate respective digital output signals at the same rate. The digital outputs of the first and second ADCs 116 and 118 are fed to respective first and second inputs of a crossover filter 120. The crossover filter 120 combines the outputs of the first and second converters to generate an output signal, “Digital Out.”

FIG. 1 also shows an analog anti-aliasing filter 110 for limiting the bandwidth of signals passed to the ADCs 116 and 118. The anti-aliasing filter preferably has a low-pass response, which cuts-off at approximately one-half the sampling rate of the converters 116 and 118 (i.e., at the Nyquist rate), or at a lower frequency.

We have recognized that analog-to-digital converters that work well at low frequencies tend to generate low frequency errors when their inputs are exposed to signals having high frequency components. To prevent these errors, an analog low-pass filter 112 is preferably connected at the input of the first ADC 116 for filtering high frequency components. An analog high-pass filter 114 may also be provided at the input of the second ADC 118 for filtering low frequency components from the input of the second ADC 118, although this is not as critical.

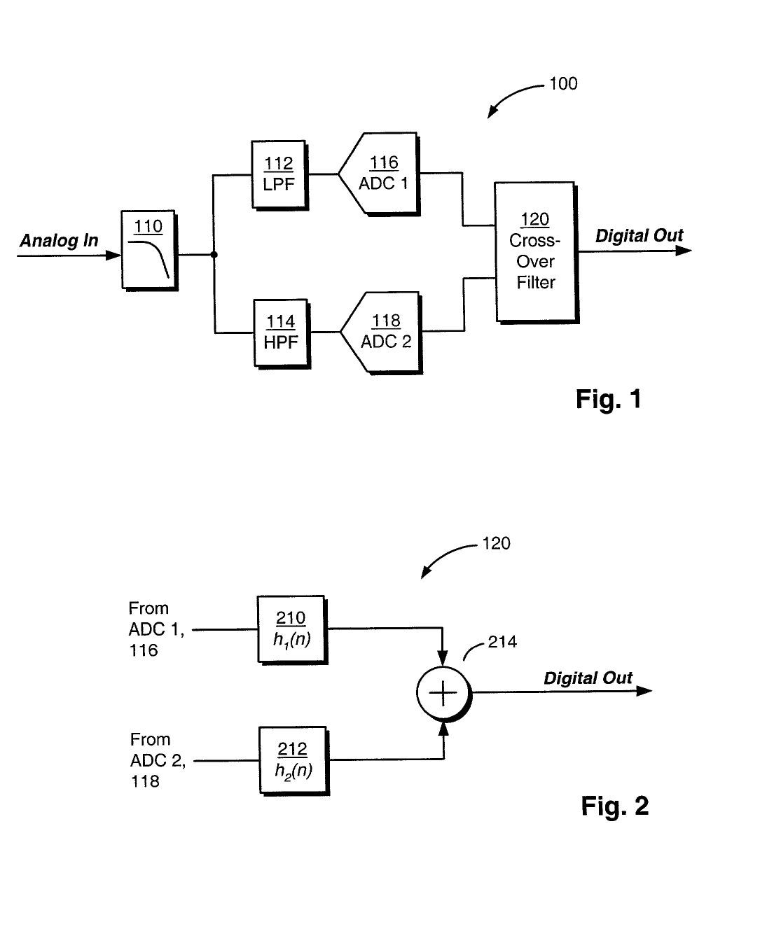

FIG. 2 shows an embodiment of the crossover filter 120. The crossover filter 120 includes a first digital filter 210 coupled to the output of the first ADC 116 and a second digital filter 212 coupled to the output of the second ADC 118. A summer 214 receives the digital outputs of the first and second digital filters 210 and 212 and adds them to produce the combined signal, Digital Out.

By appropriately balancing the characteristics of the digital filters 210 and 212, the frequency response of Digital Out versus Analog In can be adjusted as desired. We have recognized that the response of the crossover filter 120 can be made uniform (i.e., flat) by ensuring that the impulse response of the crossover filter 120, with its inputs driven together, is itself an impulse. This can be expressed mathematically as follows:

h₁(n)+h₂(n)=∂(n). EQ. 1

In EQ. 1, h₁(n) is the impulse response of the first digital filter 210, h₂(n) is the impulse response of the second digital filter 212, and δ(n) is the unit sample, or “impulse,” which is conventionally defined as

$$δ ( n ) = \{ \begin{matrix}0 , n \neq 0 \\ 1 , n = 0.\end{matrix} \qquad EQ . 2$$

In the preferred embodiment, the first digital filter 210 is a low-pass filter. Its response ensures that low-frequency components from the first ADC 116 pass to Digital Out, and that high-frequency components, for which the converter is not optimized, are blocked.

The second digital filter 212 is preferably a high-pass filter. The high-pass response of the second digital filter 212 ensures that only high-frequency components of the second ADC 118 are passed to Digital Out. This is desirable because the second ADC 118 is preferably optimized for high-frequency components.

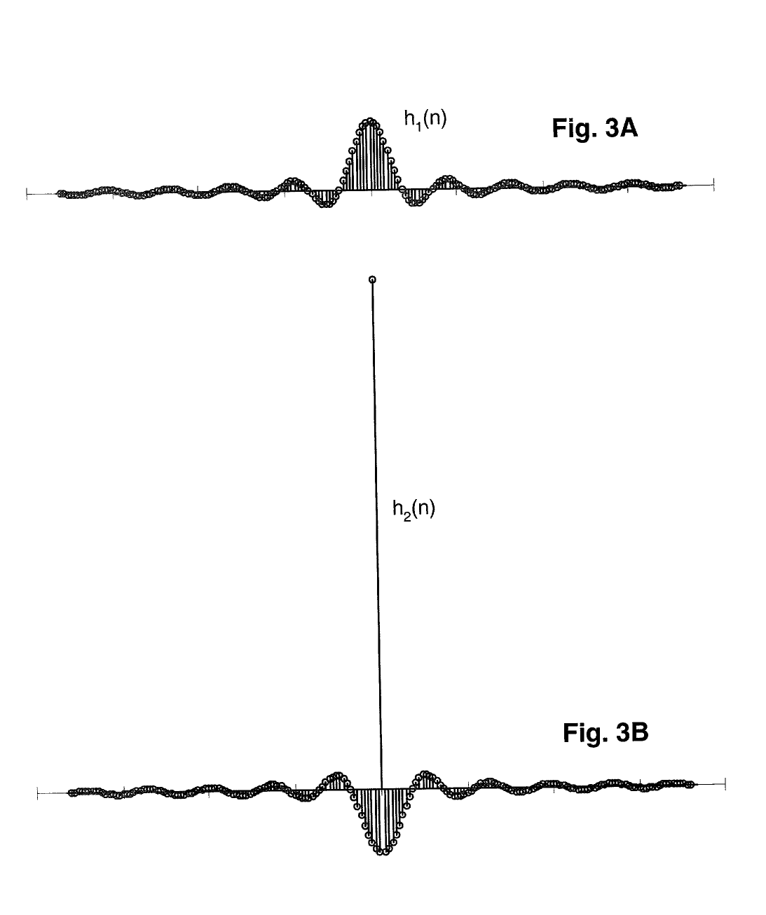

FIG. 3A shows an idealized impulse response of the low-pass filter h₁(n). Given the coefficients of h₁(n) shown in FIG. 3A, the coefficients of h₂(n) can be quickly determined to satisfy EQ. 1. As shown in FIG. 3B, the coefficients of h₂(n) are the negative of h₁(n) at all points except at n=0, at which h₂(0) equals the negative of h₁(0), plus one. Preferably, the high-pass filter represented by h₂(n) has a response of zero to DC. To ensure this result, the coefficients of h₂(n) must be made to add to zero. This is preferably accomplished by assigning the middle coefficient h₂(0) a value equal to −1 times the sum of all the other coefficients of h₂(n), and then by normalizing h₁(n) and h₂(n) so that they add to produce δ(n).

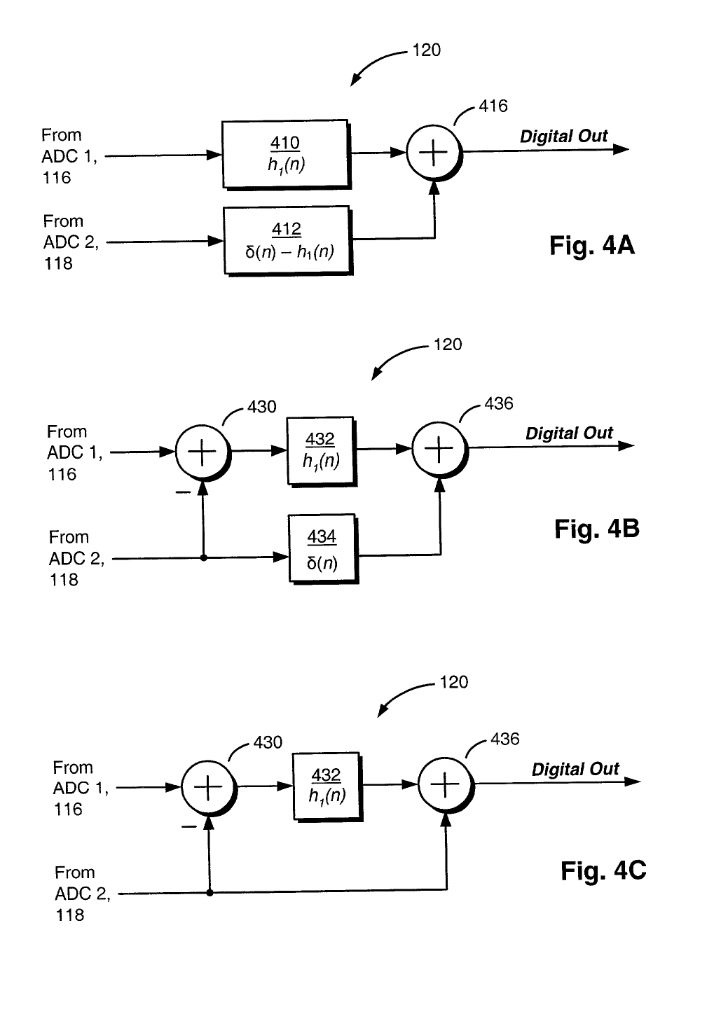

The crossover filter 120 can be simplified by considering EQ. 1. As shown in FIG. 4A, h₂(n) can be replaced by its mathematical equivalent, δ(n)−h₁(n). FIG. 4A can be further simplified by separating δ(n) from h₁(n) using conventional block diagram manipulations (See FIG. 4B). Since convolving any sequence with δ(n) yields back the original sequence, the block represented by δ(n) can be replaced by a direct connection. This is shown in FIG. 4C.

The implementation of FIG. 4C accomplishes the object of combining the outputs of the individual converters 116 and 118 into a single output. At the same time it avoids distortion.

The design of the crossover filter 120, using the constraints set forth in EQ. 1, ensures that the topology 100 has a uniform response to its inputs. However, one may not always wish to provide a uniform response. To obtain a desired response different from a uniform response, one can replace δ(n) in EQ. 1 with a desired response, h_{D}(n), as follows:

h₁(n)+h₂(n)=h_{D}(n). EQ. 3

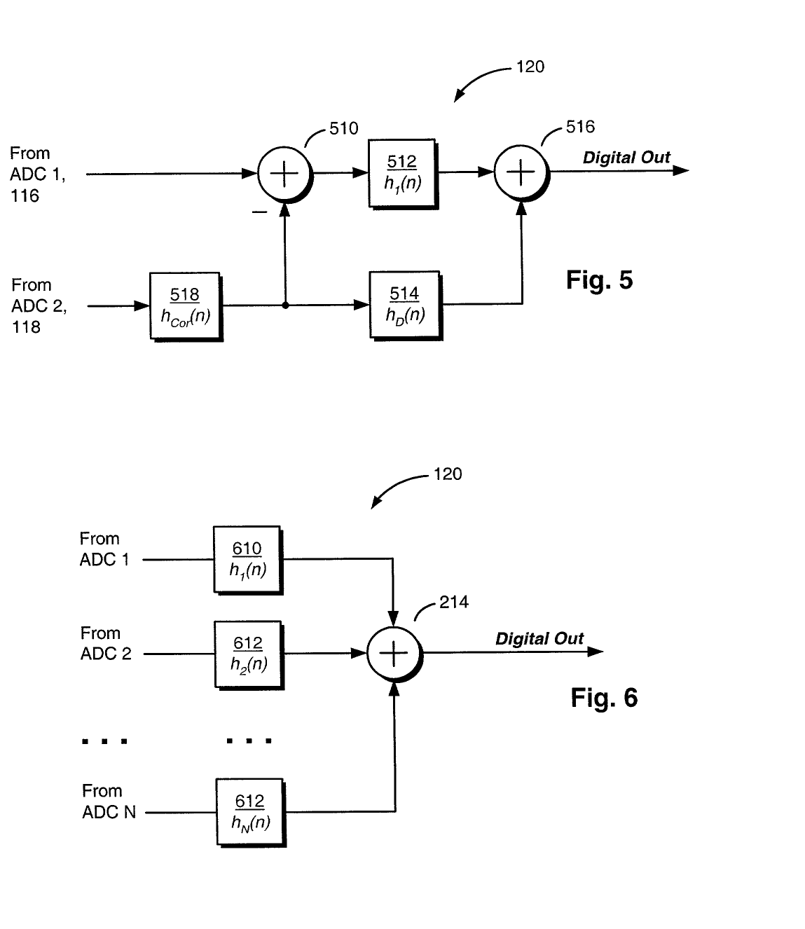

The crossover filter 120 can thus be made to provide a non-uniform response, such as an overall low-pass, band-pass, or high-pass response. FIG. 5 shows the generalized form of a crossover filter 120 that satisfies EQ. 3.

Now we consider the effects of the analog filters that precede the converters 116 and 118. Preferably, the analog low-pass filter 112 cuts off at a much higher frequency than the first digital filter 210. Therefore, the analog filter 112 has no substantial distorting effect on the overall response of the converter topology 100. In addition, the analog high-pass filter 114 preferably cuts off at a much lower frequency than the second digital filter 212. Therefore, the analog filter 114 has no substantial distorting effect on the topology 100. Although the anti-aliasing filter 110 does affect the overall response, it generally rolls off at so high a frequency that its distorting effects are irrelevant. If its effects are significant in the context of a particular application, however, they can be substantially eliminated by designing a desired response h_{D}(n) that specifically flattens the overall response.

The ability to adjust the response of the crossover filter 120 by adjusting h_{D}(n) affords the crossover filter with a great deal of flexibility. Not only can the effects of the anti-aliasing filter 110 be compensated, but also a host of other errors, such as distortion that is common to both converters 116 and 118, distortion common to both filters 112 and 114, and distortion in other circuitry.

Although h_{D}(n) can be programmed to correct for errors that are common to both inputs of the crossover filter 120, it cannot correct for errors in one input only. Correction may be needed in one path, for example, if an ADC contains errors that are not matched in its counterpart, or if an analog filter at the input of an ADC affects the signal passed to the ADC within its relevant frequency range.

Correction in one path can be achieved using an additional digital filter 518, which can be provided in series with one of the inputs of the crossover filter 120. The filter 518 can work in at least two different ways. It can be inserted in the path containing the error, where it can be programmed to provide an “anti-error” transfer function that directly flattens the error. Alternatively, it can be inserted into the path not containing the error, to specifically mimic the error inherent in the other path, thus making the error common to both inputs of the crossover filter 120. Once the error is common, it can be corrected by appropriately programming h_{D}(n).

The digital filter 518 can also correct for timing skew between the inputs of the crossover filter 120. Different types of ADCs may involve different pipeline delays, and analog filters may introduce additional delays. To correct for timing skew, the digital filter 518 can be positioned in the faster of the two paths and made to include a pipeline delay that matches the difference in delay between the two paths. The pipeline delay is preferably implemented digitally by shifting the impulse response of the filter 518 by an integer number of samples.

The digital filter 518 can also be adapted to correct for timing skew that is less than a sample period. This is preferably accomplished by borrowing a technique commonly used for performing sample rate conversion. Conceptually, the impulse response H_{Cor}(n) of the digital filter 518 is rendered as a continuous analog function H_{Cor}(x). Next, H_{Cor}(x) is determined for all x=n−ε, where ε is the fractional sample period by which the signal is to be delayed. These values H_{Cor}(n−ε) are then used in place of H_{Cor}(n) as the coefficients of the fractionally delayed filter 518. This digital technique for matching fractional delays avoids the need for using costly analog delay components such as verniers.

The digital filters h₁(n) and h_{D}(n) can be implemented in a variety of ways known to those skilled in the art, the specific form of which is not critical to the invention. We have recognized, however, that finite duration impulse response (FIR) filters offer practical advantages that are useful in the context of the present invention. First, they are relatively simple to implement as compared with other types of filters. Second, they can provide linear phase. Linear phase is highly desirable because it allows signals to be passed with a minimum of timing distortion.

In the preferred embodiment, h₁(n) is realized with a 97-point FIR filter. The filter is made causal by shifting its impulse response by 48 samples ((L−1)/2, L=97). For alignment in time with h₁(n), the output of the second ADC 118 is delayed 48 samples enroute to the second summer 436 (see FIG. 4C).

If the crossover filter 120 is to assume a desired response h_{D}(n) different from an impulse, h_{D}(n) can been adequately realized with a 33-point FIR filter. Since the 33-point filter already entails a delay of 16 samples for causality, a net delay of only 32 samples need to be added to achieve both alignment with h₁(n) and causality.

When setting the cut-off frequency of the digital filter 210, it is beneficial to consider the noise contributions of the two ADCs 116 and 118. In the preferred embodiment, the first ADC 116 is a sigma-delta converter optimized for measuring low-frequency components. It has relatively low noise at low frequencies, but its noise increases with increasing input frequency. The second ADC 118 is preferably either a flash sub-ranging converter or a successive approximation converter. The second ADC works well at high frequencies and has a relatively flat noise response. As input frequency increases, the noise of the first ADC approaches and eventually exceeds the noise of the second ADC. It is therefore advisable to set the cut-off frequency of the digital filter 210 to less than or equal to the crossover frequency of the two noise responses, to minimize the overall noise transmitted to Digital Out.

Preferably, the crossover filter 120 is realized using special-purpose digital signal processing (DSP) hardware. However, it can also be realized using conventional digital hardware, or using microprocessors or general-purpose computers running DSP algorithms.

Alternatives

Having described one embodiment, numerous alternative embodiments or variations can be made. For example, the preferred embodiment described above shows only first and second ADCs 116 and 118. The invention is not limited to two converters, however. Additional converters can be used, as shown in FIG. 6, with each converter covering a different portion of a desired overall frequency range. Different digital filtering is associated with each converter. To blend the outputs of the ADCs to produce a uniform response, the crossover filter should substantially satisfy the equation

h₁(n)+h₂(n)+ . . . +h_{N}(n)=∂(n), EQ. 4

where h_{N}(n) is the impulse response of the N^{th} digital filter associated with the N^{th} ADC. If a non-uniform response is desired, the following equation should be used instead of EQ. 4 to govern the filter design:

h₁(n)+h₂(n)+ . . . +h_{N}(n)=h_{D}(n). EQ. 5

As described above, the correction filter 518 is preferably provided in series with only one input of the crossover filter 120. This is only an example, however. Alternatively, different correction filters could be provided in series with different inputs. For example, where two converters are used, one correction filter 518 could be included in one path to correct for frequency response errors, and another could be provided in the other path to correct for timing errors. Where greater than two converters are used, the output of any of the converters can be provided with a correction filter. The correction filters for the different paths can be programmed in an attempt to compensate frequency response and timing errors particular to the individual inputs of the crossover filter 120.

The first digital filter 210 is described above as being a low-pass filter. However, other types of filters can be used, such as band-pass, notch, comb, or high-pass filters, depending upon the demands of the particular application. In addition, as described above, a rectangular window is used to shape the low-pass filter. However, other types of windows can be used, such as Hamming, Hanning, Kaiser, or Blackman windows. Alternatively, digital low-pass filters may be designed in other ways. In applications where more than two ADCs are used, each filter can be implemented as a band-pass filter, the form of which can be varied substantially, as long as the overall crossover filter response substantially meets EQ. 4 or EQ. 5.

In the preferred embodiment, the first and second ADCs 116 and 118 are clocked together, i.e., both ADC's convert their respective versions of the analog input signal simultaneously. However, this is not required. Alternatively, a divided version of the conversion clock can be fed to the slower-sampling ADC. The empty locations left by the slower converter could be filled with previously sampled data, or with fixed or interpolated data. With the empty locations filled in, the crossover filter 120 is able to combine data from both converters, substantially as described above, as if the converters were producing output data at the same rate.

Each of these alternatives and variations, as well as others, has been contemplated by the inventor and is intended to fall within the scope of the instant invention. It should be understood, therefore, that the foregoing description is by way of example, and the invention should be limited only by the spirit and scope of the appended claims.

What is claimed is:

1. A circuit for converting an analog signal into a digital signal, comprising:
an analog input for conveying an analog input signal;
a plurality of analog-to-digital converters each having an input coupled to the analog input, and each having an output; and
a crossover filter having a plurality of inputs each coupled to the output of a different one of the plurality of analog-to-digital converters, and having a digital output for providing a digital representation of the analog input signal.

2. A circuit as recited in claim 1, wherein the crossover filter has a different frequency response for each of the plurality of inputs of the crossover filter.

3. A circuit as recited in claim 2, wherein the different frequency responses of the crossover filter add to substantially equal a desired overall response of the crossover filter.

4. A circuit as recited in claim 2, wherein the desired overall response of the crossover filter is itself an impulse.

5. A circuit as recited in claim 3, wherein the desired overall response of the crossover filter corrects for an error that is common to the outputs of all of the plurality of analog-to-digital converters.

6. A circuit as recited in claim 2, further comprising a correcting filter coupled in series with the output of one of the plurality of analog-to-digital converters for correcting an error at the output of the respective analog-to-digital converter.

7. A circuit as recited in claim 2, further comprising a correcting filter coupled in series with the output of one of the plurality of analog-to-digital converters for correcting an error at the output of another of the plurality of analog-to-digital converters.

8. A circuit as recited in claim 7, wherein the correcting filter corrects for a delay in the output of the other of the plurality of analog-to-digital converters.

9. A circuit for converting an analog signal into a digital signal, comprising:
an analog input for conveying an analog input signal;
a first analog-to-digital converter having an input and an output, the input being coupled to the analog input;
a second analog-to-digital converter having an input and an output, the input being coupled to the analog input; and
a crossover filter having first and second inputs respectively coupled to the outputs of the first and second analog-to-digital converters, and having a digital output for providing a digital representation of the analog input signal.

10. A circuit as recited in claim 9, wherein the crossover filter comprises:
a first adder having a first input coupled to the output of the first analog-to-digital converter, a second input coupled to the output of the second analog-to-digital converter, and an output for providing a difference between the first and second inputs;
a digital filter having an input and an output, the input coupled to the output of the first adder;
a second adder having a first input coupled to the output of the digital filter, a second input coupled to the output of the second analog-to-digital converter, and an output providing an output signal representative of a combination of the outputs of the first and second analog-to-digital converters.

11. A circuit as recited in claim 10, wherein the digital filter is a low-pass filter.

12. A circuit as recited in claim 10, wherein the digital filter is a first digital filter, the crossover filter further comprising:
a second digital filter coupled in series between the output of the second analog-to-digital converter and the second input of the second adder,
wherein the second digital filter substantially prescribes an overall desired response of the crossover filter.

13. A circuit as recited in claim 10, further comprising an analog low-pass filter coupled in series between the analog input and the first analog-to-digital converter.

14. An analog-to-digital multi-converter topology, comprising:
an analog input for conveying an analog input signal;
a plurality of analog-to-digital converters each having an input coupled to the analog input, and each having an output; and
filtering means, coupled to the output of each of the plurality of analog-to-digital converters, for filtering the outputs of the plurality of analog-to-digital converters to provide a digital representation of the analog input signal.

15. A method of converting an analog signal into a digital signal, comprising:
(A) conveying the analog signal to a plurality of analog-to-digital converters;
(B) converting, via the plurality of the analog-to-digital converters, the analog signal into a plurality of digital signals;
(C) digitally filtering the plurality of digital signals to produce a combined digital signal representative of the analog signal.

16. A method as recited in claim 15, wherein the step of digitally filtering includes applying a different filtering transfer function to each of the plurality of digital signals.

17. A method as recited in claim 16, wherein a sum of the different filtering transfer functions substantially equals a desired overall response.

18. A method as recited in claim 15, wherein the desired overall response corrects for an error that is common to the outputs of the plurality of analog-to-digital converters.

19. A method as recited in claim 17, wherein the desired overall response is an impulse.

20. A method as recited in claim 15, further comprising digitally filtering the output of one of the analog-to-digital converters to correct for an error at the output of one of the plurality of analog-to-digital converters.
